(19) United States
(12) Patent Application Publication
(10) Pub. No.: US 2012/0249911 A1
(43) Pub. Date: Oct. 4, 2012

(54) LIQUID CRYSTAL DISPLAY DEVICE AND METHOD OF MANUFACTURING LIQUID CRYSTAL DISPLAY DEVICE

(75) Inventors: Takashi Kamino, Kumamoto (JP); Moriyasu Nagura, Kumamoto (JP)

(73) Assignee: Sony Corporation, Tokyo (JP)

(21) Appl. No.: 13/426,864

(22) Filed: Mar. 22, 2012

(30) Foreign Application Priority Data
Mar. 30, 2011 (JP) 2011-076112

(51) Int. Cl. G02F 1/136; H01L 33/08

(52) U.S. Cl. 349/42; 438/30; 257/E33.067

(57) ABSTRACT

A liquid crystal display device includes: a drive element substrate having plural interlayer insulating films laminated thereon, and having a non-opening area in which signal lines and a transistor are provided and an opening area in which none of the signal lines and the transistors is provided in the plural interlayer insulating films; and a counter substrate provided so as to face the drive element substrate through a liquid crystal, in which the drive element substrate includes: an insulating portion which is provided in the interlayer insulating film(s) between the non-opening area and the opening area, and whose refractive index is different from that of (each of) the interlayer insulating film(s); and a light blocking film provided between the insulating portion and the counter substrate.

### BACKGROUND

The present disclosure relates to a liquid crystal display device and a method of manufacturing the liquid crystal display device.

It is known that in a liquid crystal display device utilized in an image projector apparatus and the like, when a light is made incident to a channel portion of a transistor formed on a drive element substrate, a photo-leakage current is generated to exert a bad influence on an image quality.

With regard to a method of reducing the influence of the photo-leakage current, for example, Japanese Patent Laid-Open No. 2005-321670 discloses a technique for implanting ions into interlayer insulating films laminated on a drive element substrate, thereby making refractive indices of an opening area and a non-opening area in the drive element substrate different from each other. With the technique disclosed in Japanese Patent Laid-Open No. 2005-321670, an incident light to the non-opening area including a channel portion of a transistor can be reflected and reduced, thereby reducing the influence of the photo-leakage current. Here, the opening area means an area corresponding to a portion of a grid pattern surrounded by scanning lines and signal lines in a structure in which plural scanning lines and plural signal lines are disposed in a grid-like lattice so as to be perpendicular to each other in a drive element substrate. In addition, the non-opening area means an area in which either the scanning lines or signal lines composing the opening area exist.

### SUMMARY

The method of implanting the ions into the interlayer insulating films involves a problem that a difference in refractive index between the portion into which the ions are implanted, and the position into which none of the ions is implanted is very small. In addition, there is also caused a problem that a density distribution of the ions implanted spreads and thus a clear boundary line of the refractive index is not formed. Due to these problems, even when the ions are implanted into the interlayer insulating films, it may be impossible to sufficiently reduce the photo-leakage current.

The present disclosure has been made in order to solve the problems described above, and it is therefore desirable to provide a liquid crystal display device in which a photo-leakage current can be reduced, thereby improving an image quality, and a method of manufacturing the same.

In order to attain the desire described above, according to an embodiment of the present disclosure, there is provided a liquid crystal display device including: a drive element substrate having plural interlayer insulating films laminated thereon, and having a non-opening area in which signal lines and a transistor are provided and an opening area in which none of the signal lines and the transistor is provided in the plural interlayer insulating films; and a counter substrate provided so as to face the drive element substrate through a liquid crystal, in which the drive element substrate includes: an insulating portion which is provided in the interlayer insulating film(s) between the non-opening area and the opening area, and whose refractive index is different from that of (each of) the interlayer insulating film(s); and a light blocking film provided between the insulating portion and the counter substrate.

The insulating portion whose refractive index is different from that of (each of) the interlayer insulating film(s) is provided in the interlayer insulating film(s) between the non-opening area and the opening area, whereby the incident light becomes hard to enter the transistor, and thus the photo-leakage current can be suppressed, thereby improving the image quality.

According to another embodiment of the present disclosure, there is provided a method of manufacturing a liquid crystal display device including a drive element substrate having a non-opening area in which signal lines and a transistor are provided and an opening area in which none of the signal lines and the transistor is provided, and a counter substrate provided so as to face the drive element substrate through a liquid crystal, the manufacturing method including: forming plural interlayer insulating films, and forming the signal lines and the transistor in the non-opening area in the interlayer insulating film(s); forming an insulating portion whose refractive index is different from that of (each of) the interlayer insulating film(s) between the non-opening area and the opening area of the interlayer insulating film(s); and forming a light blocking film between the insulating portion of the non-opening area, and the counter substrate.

As set forth hereinabove, according to the present disclosure, the photo-leakage current can be reduced, thereby improving the image quality.

### BRIEF DESCRIPTION OF THE DRAWINGS

FIGS. 1A and 1B are respectively a top plan view showing a structure of a liquid crystal display device according to a first embodiment of the present disclosure, and a cross sectional view taken on line A-A′ of FIG. 1A;

FIG. 2 is a partial enlarged view of a portion surrounded by a circle in FIG. 1A;

FIGS. 3A and 3B are respectively a cross sectional view taken on line B-B′ of FIG. 2, and a view showing refractive indices of an interlayer insulating film and an insulating portion each shown in FIG. 3A;

FIGS. 4A to 4E are respectively a top plan view when a non-opening area of a third interlayer insulating film is viewed from a second interlayer insulating film in a liquid crystal display device according to a second embodiment of the present disclosure, a top plan view when the third interlayer insulating film is excluded from FIG. 4A, a cross sectional view taken on line A-A′ of FIG. 4A, a cross sectional view taken on line B-B′ of FIG. 4A, and a cross sectional view taken on line C-C′ of FIG. 4A;

FIGS. 5A, 5B, and 5C are respectively a partial cross sectional view in the liquid crystal display device according to the second embodiment of the present disclosure, a view showing a relationship between a refractive index and a position, and a view showing a portion surrounded by a circle in FIG. 5A;

FIGS. 6A to 6E are respectively cross sectional views explaining a method of manufacturing the liquid crystal display device according to the second embodiment of the present disclosure in the order of processes;

FIGS. 7A, 7B, and 7C are respectively a partial cross sectional view in a liquid crystal display device according to a third embodiment of the present disclosure, a view showing a relationship between a refractive index and a position, and a view showing a portion surrounded by a circle in FIG. 7A;

FIGS. 8A to 8D are respectively cross sectional views explaining a method of manufacturing the liquid crystal display device according to the third embodiment of the present disclosure in the order of processes;

FIGS. 9A and 9B are respectively a cross sectional view showing a structure of a liquid crystal display device according to a change of the third embodiment of the present disclosure, and a view showing refractive indices of an interlayer insulating film and an insulating portion each shown in FIG. 9A;

FIGS. 10A to 10E are respectively a top plan view when a non-opening area of a third interlayer insulating film is viewed from a second interlayer insulating film in a liquid crystal display device according to a fourth embodiment of the present disclosure, a top plan view when the third interlayer insulating film is excluded from FIG. 10A, a cross sectional view taken on line A-A′ of FIG. 10A, a cross sectional view taken on line B-B′ of FIG. 10A, and a cross sectional view taken on line C-C′ of FIG. 10A; and

FIGS. 11A and 11B are respectively a partial cross sectional view in a liquid crystal display device according to a fifth embodiment of the present disclosure, and a view showing a relationship between a refractive index and a position.

### DETAILED DESCRIPTION OF THE PREFERRED EMBODIMENTS

Embodiments of the present disclosure will be described in detail hereinafter with reference to the accompanying drawings.

### First Embodiment

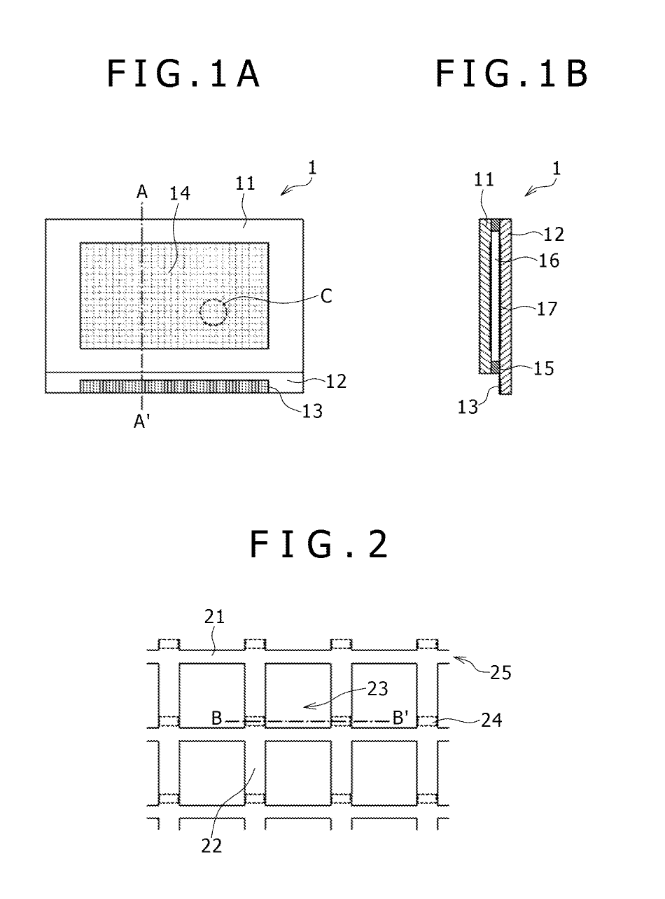

FIG. 1A is a top plan view showing a structure of a liquid crystal display device 1 according to a first embodiment of the present disclosure. FIG. 1B is a cross sectional view of the liquid crystal display device 1 along line A-A′ of FIG. 1A.

The liquid crystal display device 1 includes a drive element substrate 12 and a counter substrate 11 which face each other through a liquid crystal 16. A drive element 17 is provided on one plate surface side of the drive element substrate 12. The counter substrate 11 has a pixel area in which display pixels 14 are provided. The counter substrate 11 and the drive element substrate 12 are adhered to each other through a sealing member 15, and have a structure in which a liquid crystal layer composed of the liquid crystal 16 is held between their plate surfaces facing each other.

The drive element substrate 12 is provided with a connection terminal 13 through which the liquid crystal display device 1 is connected to an external apparatus (not shown). Specifically, each of the drive element substrate 12 and the counter substrate 11 has a rectangular plate-like shape. The drive element substrate 12 is longer in size in one direction (in a vertical direction in FIGS. 1A and 1B) along an external form having the rectangular shape than that of the counter substrate 11. Therefore, in a state in which the drive element substrate 12 and the counter substrate 11 are piled up each other so as to hold the liquid crystal 16 between them, a side of one side of the plate surface of the drive element substrate 12 holding the liquid crystal 16 together with the counter substrate 11 is partially exposed. The connection terminal 13 is provided in the exposed plate surface portion of the drive element substrate 12.

FIG. 2 is a partial enlarged view showing an area C surrounded by a circle indicated by a broken line shown in FIG. 1A. The drive element 17 includes plural scanning lines 21, plural signal lines 22, and plural Thin Film Transistors (TFTs) 24.

The plural scanning lines 21 are formed so as to become approximately parallel with one another along a transverse line direction (a horizontal direction in FIG. 1A) of an arrangement of the display pixels 14. The plural signal lines 22 are formed so as to become approximately parallel with one another along a longitudinal line direction (a vertical direction in FIG. 1A) of the arrangement of the display pixels 14. In a word, the scanning lines 21 and the signal lines 22 are disposed so as to become perpendicular to each other on a surface approximately parallel with a screen composed of the display pixels 14. Therefore, the scanning lines 21 and the signal lines 22 are disposed in a grid lattice.

A grid portion of a grid pattern in the grid lattice-like disposition of the scanning lines 21 and the signal lines 22, that is, a square-like area surrounded by the scanning lines 21 and the signal lines 22 is referred to as “an opening area 23.” In addition, an area in which the scanning lines 21 and the signal lines 22 forming the opening area 23 is referred to as “a non-opening area 25.”In a word, the opening area 23 is the area surrounded by the non-opening area 25. Also, the wirings such as the scanning lines 21 and the signal lines 22, and the transistors such as the TFTs 24 are not provided in the opening area 23. The non-opening area 25 is an area in which a light is blocked by the scanning lines 21, the signal lines 22, and the like.

The TFT 24 is composed of a transistor made from a semiconductor. The TFT 24 is disposed in the non-opening area 25. Specifically, the TFT 24 is formed in the vicinity of an intersection between the scanning line 21 and the signal line 22.

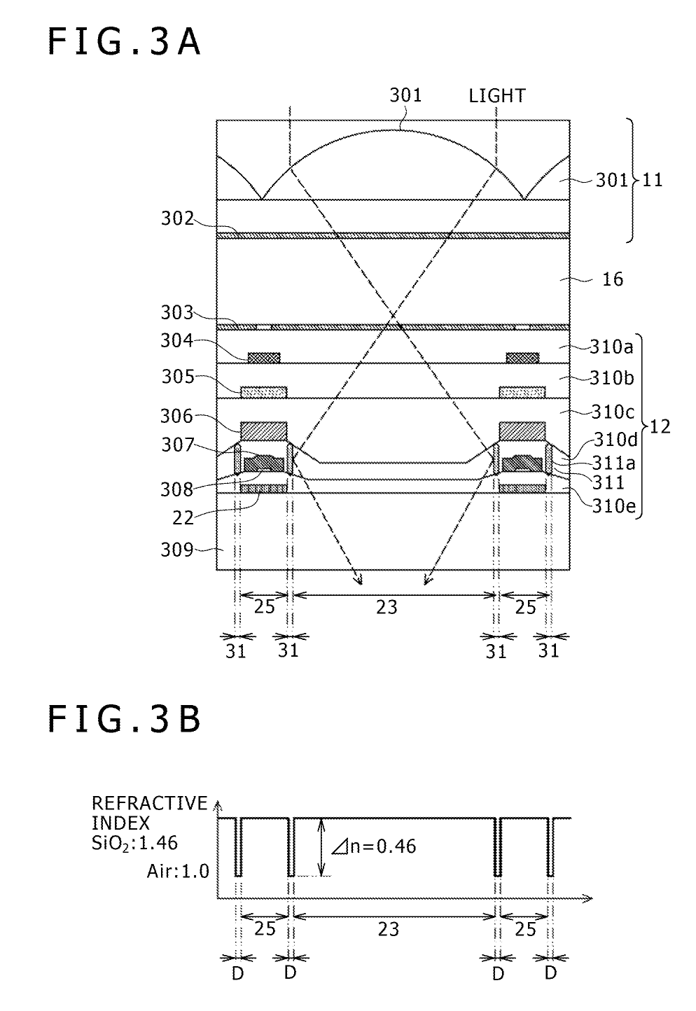

FIG. 3A is a cross sectional view taken on line B-B′ of FIG. 2, and schematically shows a cross section of the liquid crystal display device 1. As shown in FIG. 3A, in a structure in which the drive element substrate 12 and the counter substrate 11 are disposed so as to face each other in a state in which the liquid crystal 16 is held between the drive element substrate 12 and the counter substrate 11, a microlens 301 is provided on a side opposite to the liquid crystal 16 side of the counter substrate 11. The microlens 301 condenses a light emitted from a light source (not shown). A counter transparent electrode 302 is provided between the counter substrate 11 and the liquid crystal 16. In a word, the counter transparent electrode 302 is formed on a back surface side of the microlens 301.

The drive element substrate 12 includes five layers of interlayer insulating films 310a to 310e which are provided from the side facing the counter substrate 11, and a glass substrate 309. In a word, the drive element substrate 12 is provided with a lamination structure of insulating films in which the first interlayer insulating film 310a, the second interlayer insulating film 310b, the third interlayer insulating film 310c, the fourth interlayer insulating film 310d, and the fifth interlayer insulating film 310e are laminated in this order from the side of the liquid crystal 16 which is held between the drive element substrate 12 and the counter substrate 11. Also, the glass substrate 309 is provided on the outside of this lamination structure in a word, on the side of the fifth interlayer insulating film 310e opposite to the fourth interlayer insulating film 310d. Both of the opening area 23 and the non-opening area 25 are provided in the drive element substrate 12 having such a structure.

The non-opening area 25, as described above, is the area in which the light is blocked by the scanning lines 21, the signal lines 22, and the like. FIG. 3A is a cross sectional view which crosses at right angles the two signal lines 22 in planar view in a range including the signal lines 22 in the two portions in relation to FIG. 2. Referring to FIG. 3A, the signal lines 22 each serving as the light blocking portion in the non-opening area 25 are shown on both of the right and left sides.

In the drive element substrate 12, the two signal lines 22 in both of the non-opening area 25 are provided in the layer of the fifth interlayer insulating film 310e. Specifically, the two signal lines 22 are provided on the glass substrate 309, and are covered with the fifth interlayer insulating film 310e formed on the glass substrate 309, thereby being located within the layer of the fifth interlayer insulating film 310e.

In addition, as shown in FIG. 3A, in each of the non-opening areas 25 of the drive element substrate 12, the TFT 24 (refer to FIG. 2) formed in the vicinity of the intersection portion between the scanning line 21 and the signal line 22 as described above is provided within the layer of the fourth interlayer film 310d. The TFT 24 has both of a channel portion 308 and a gate line 307.

Also, in addition to the signal lines 22, a signal wiring 306 provided within the layer of the third interlayer insulating film 310c, a light blocking film 305 provided within the layer of the second interlayer insulating film 310b, and a pixel electrode wiring 304 provided within the first interlayer insulating film 310a exist as the light blocking portion in each of the non-opening areas 25 of the drive element substrate 12. In other words, the signal wiring 306, the light blocking film 305, and the pixel electrode wiring 304 are formed so as to be located in each of the non-opening areas 25. The pixel transparent electrode 303 is provided between the first interlayer insulating film 310a and the liquid crystal 16. In a word, the liquid crystal 16 is enclosed into a space defined between the counter transparent electrode 302 provided on the counter substrate 11 side, and the pixel transparent electrode 303 provided on the drive element substrate 12 side.

As described above, in the non-opening area 25, in addition to the signal lines 22, plural light blocking portions such as the light blocking film 35 are provided in the layers, respectively, in the lamination structure composed of the interlayer insulating films. In the portion of the drive element substrate 12 shown in FIG. 3A, parts of the right- and left-hand sides are the non-opening areas 25, respectively, and an intermediate portion sandwiched between the non-opening areas 25 is the opening area 23.

In such a disposition relationship between the opening area 23 and the non-opening areas 25, the microlenses 301 which the counter substrate 11 has are provided so as to correspond to the square opening areas 23, respectively, in the manner as described above. Specifically, the microlens 301 is formed in such a way that an optical axis center thereof agrees with the square center of the opening area 23, and thus condenses the light to the square opening area 23. Therefore, a position of the non-opening area 25 corresponds to a boundary portion between each adjacent two microlenses 301 in the planar view.

In the drive element substrate 12 having the structure as described above, an insulating portion 311 is provided in the boundary portion between the square opening area 23 and the non-opening area 25. The insulating portion 311 is a portion in which a void 311a is formed in the fourth interlayer insulating film 310d, and is also a portion in which air is held in the void 311a. Specifically, the void 311a holding the air in the insulating portion 311, for example, is formed by carrying out etching for the fourth interlayer insulating film 310d. However, a method of forming the void 311a is especially by no means limited. Thus, in addition to the etching method, for example, a method using mechanical processing, or the like may also be utilized.

As has been described, in the first embodiment, the insulating film 311 is the portion in which the air is held in the void 311a, and thus has a refractive index different from that of the interlayer insulating film (the fourth interlayer insulating film 310d in the first embodiment) in which the insulating portion 311 is provided.

FIG. 3B is a view showing refractive indices of the fourth interlayer insulating film 310d and the insulating film 311. When the fourth interlayer insulating film 310d is made of SiO₂, the refractive index of the fourth interlayer insulating film 310d is 1.46. On the other hand, the refractive index of the insulating portion 311 is 1.00 because the insulating portion 311 is substantially made of the air held in the void 311a. Therefore, a difference in refractive index between the fourth interlayer insulating film 310d and the insulating film 311 becomes 0.46. When attention is paid to such a difference in refractive index between the fourth interlayer insulating film 310d and the insulating film 311, the fourth interlayer insulating film 310d has a structure in which the opening area 23 and the non-opening area 25 is separated from each other through the wall surface having the refractive index of 0.46 by the insulating portion 311 formed in the low refractive index area 31. In a word, the insulating portion 311 is provided approximately across the entire film thickness direction (the vertical direction in FIG. 3A) in the fourth interlayer insulating film 310d. The fourth interlayer insulating film 310d is partitioned into a portion corresponding to the opening area 23, and a portion corresponding to the non-opening area 25 by the insulating portion 311.

As shown in FIG. 3A, the light which has been made incident to the counter substrate 11 is refracted by the microlens 301, and is transmitted through the liquid crystal 16 to reach the drive element substrate 12. At this time, since the light (refer to an arrow indicated by a broken line) which is travelling toward the channel portion 308 of the transistor is reflected by the surface of the insulating portion 311, the light becomes hard to reach the channel portion 308 of the transistor. If no insulating portion 311 is provided, a part (indicated by the arrow of the broken line) of the light made incident to the counter substrate 11 reaches the channel portion 308 of the transistor without being blocked by the insulating portion 311. When the light is made incident to the channel portion 308 of the transistor, the photo-leakage current is generated to exert a bad influence on the image quality. In the first embodiment, the insulating portion 311 is provided between the opening area 23 and the non-opening area 25 of the fourth interlayer insulating film 310d, whereby the light made incident from the opening area 23 is reflected by the insulating portion 311, and thus the light becomes hard to reach the channel portion 308 of the transistor. As a result, the photo-leakage current generated in the transistor having the channel portion 308 and the gate line 307 is suppressed.

As described above, in the liquid crystal display device 1 according to the first embodiment of the present disclosure, the insulating portion 311 whose refractive index is different from that of the fourth interlayer insulating film 310d is provided between the opening area 23 and the non-opening area 25 of the fourth interlayer insulating film 310d. As a result, the incident light can be prevented from entering the channel portion 308 of the transistor, the photo-leakage current generated in the transistor can be suppressed, and thus the image quality of the liquid crystal display device 1 can be improved.

### Second Embodiment

Next, a liquid crystal display device 2 according to a second embodiment of the present disclosure will be described in detail. The liquid crystal display device 2 has the same structure as that of the liquid crystal display device 1 shown in FIG. 3A except that each of interlayer insulating films in which an insulating portion 411 is provided is different from that in the liquid crystal display device 1 shown in FIG. 3A. It is noted that the same portions as those in the liquid crystal device 1 of the first embodiment are designated by the same reference numerals or symbols, respectively, and a description is omitted here for the sake of simplicity. The insulating portion 411 of the liquid crystal display device 2 is provided across parts of the third interlayer insulating film 310c and the fourth interlayer insulating film 310d.

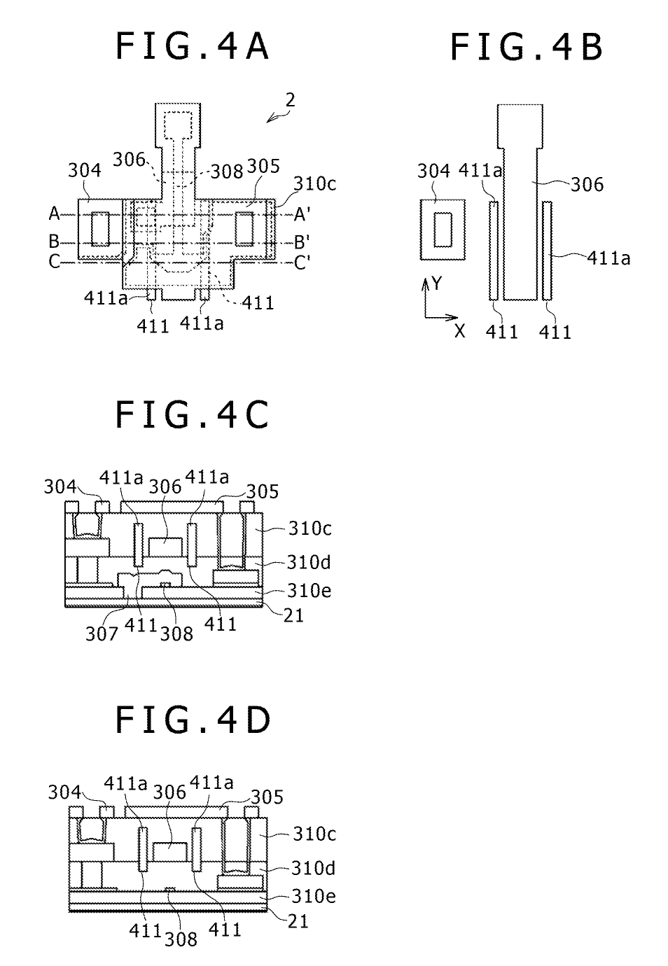

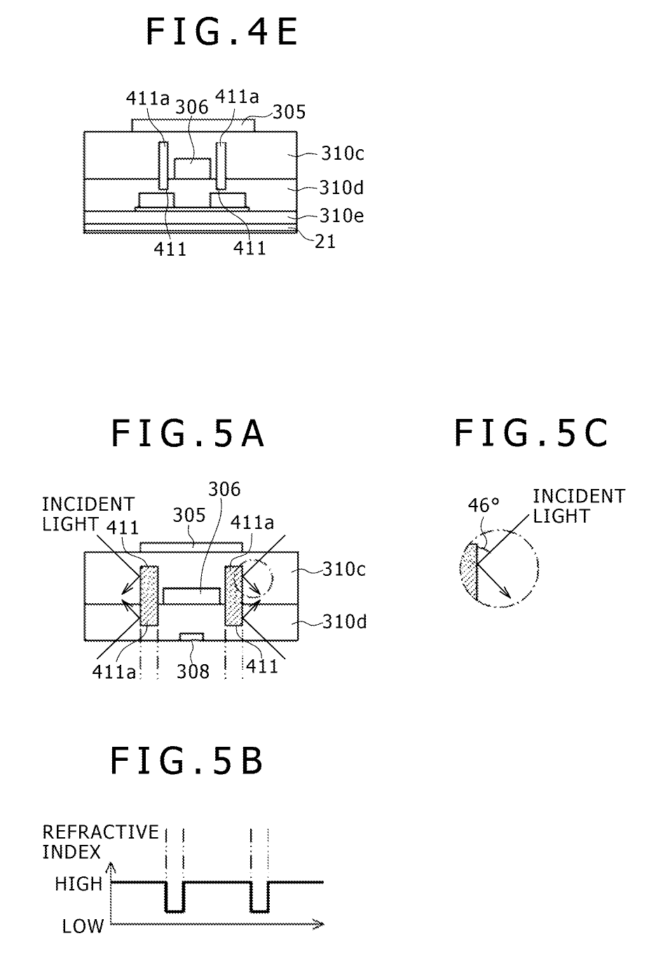

FIGS. 4A to 4E are respectively views each showing the non-opening area 25 including the third and fourth interlayer insulating films 310c and 310d across the parts of which the insulating portion 411 is provided.

FIG. 4A is a top plan view when the non-opening area 25 of the third interlayer insulating film 310c is viewed from the second interlayer insulating film 310b side. FIG. 4B is a top plan view in which the layer of the third interlayer insulating film 310c is excluded from FIG. 4A. As shown in FIG. 4B, the insulating portions 411 in the liquid crystal display device 2 of the second embodiment are provided so as to hold the signal wiring 306 between them.

FIG. 4C is a cross sectional view taken on line A-A′ of FIG. 4A, FIG. 4D is a cross sectional view taken on line B-B′ of FIG. 4A, and FIG. 4E is a cross sectional view taken on line C-C′ of FIG. 4A.

The drive element substrate 12 includes the insulating portions 411 each formed in the boundary portion between the opening area 23 and the non-opening area 25 of the third and fourth interlayer insulating films 310c and 310d. Each of the insulating portions 411 is a portion in which a void 411a is formed in the third and fourth interlayer insulating films 310c and 310d, and is also a portion in which air is held in the void 411a. The insulating portions 411 are formed so as to surround both sides of the channel portion 308 from an upper portion. As will be described later, each of the insulating portions 411 is formed by providing a trench across the parts of the third and fourth interlayer insulating films 310c and 310d by carrying out etching.

Each of the third and fourth interlayer insulating films 310c and 310d, for example, is made of SiO₂, and a refractive index thereof is 1.46. The refractive index of the insulating portion 411 is 1.00 because the insulating portion 411 is substantially made of the air held in the void 411a. Therefore, a difference in refractive index between each of the third and fourth interlayer insulating films 310c and 310d, and the insulating film 411 becomes 0.46. As has been described, each of the insulating portions 411 has the refractive index different from that of each of the interlayer insulating films (the third and fourth insulating films 310c and 310d in the second embodiment) across the parts of which the insulating portion 411 is provided.

When attention is paid to such a difference in refractive index between each of the third interlayer insulating film 310c and the fourth interlayer insulating film 310d, and the insulating film 411, the third and fourth interlayer insulating films 310c and 310d have a structure in which the opening area 23 and the non-opening area 25 is separated from each other through the wall surface having the refractive index of 0.46 by the insulating portion 411. In a word, the insulating portion 411 is provided approximately across the entire film thickness direction in the third and fourth interlayer insulating films 310c and 310d. The third and fourth interlayer insulating films 310c and 310d are partitioned into a portion corresponding to the opening area 23, and a portion corresponding to the non-opening area 25 by the insulating portion 411.

A description will be given below with respect to the effect that the incident light becomes hard to enter the channel portion 308 of the transistor due to the provision of the insulating portions 411 with reference to FIGS. 5A to 5C. As shown in FIG. 5B, the refractive index of the insulating portion 411 is lower than that of each of the third and fourth interlayer insulating films 310c and 310d.

The light which has been made incident to the counter substrate 11 is refracted by the microlens 301, and is transmitted through the liquid crystal 16 to reach the drive element substrate 12.

Referring back to FIG. 5A, the incident light which has reached the drive element substrate 12 either directly reaches the surface of the insulating portion 411 or is reflected by the glass substrate 309, the electrode, and the like to reach the surface of the insulating portion 411. The incident light which has reached the surface of the insulating portion 411 is reflected by the surface of the insulating portion 411 in accordance with the Snell's law to be emitted from the opening area 23.

FIG. 5C is a view showing a portion surrounded by a circle indicated by a dashed line in FIG. 5A. As shown in FIG. 5C, the incident light whose incident angle is equal to or smaller than a critical angle (46° in this case) is totally reflected. As a result, the light entering the channel portion 308 of the transistor is reduced, thereby making it possible to suppress the generation of the photo-leakage current.

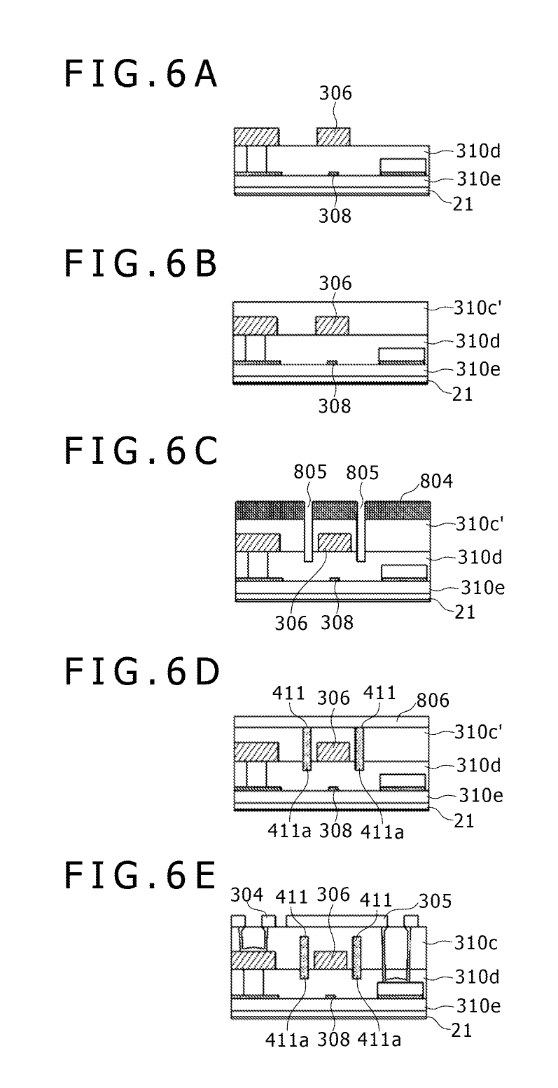

Next, a method of manufacturing the liquid crystal device 2 will be described with reference to FIGS. 6A to 6E. FIGS. 6A to 6E are respectively cross sectional views each taken on line B-B′ of FIG. 4A.

As shown in FIG. 6A, the channel portion 308 of the transistor, the gate line 307 and the pixel electrode wiring 304 are formed on the glass substrate 309 (307, 304 and 309 are shown in FIG. 3A), and the fourth interlayer insulating film 310d is then deposited thereon. The signal wiring 306 is formed on the fourth interlayer insulating film 310d. The signal wiring 306, for example, is made of aluminum or the like.

Next, as shown in FIG. 6B, a third interlayer insulating film 310c′ is deposited on the signal wiring 306. Subsequently, as shown in FIG. 6C, a resist material 804 for masking is deposited on the third interlayer insulating film 310c′. After completion of the deposition of the resist material 804, the resist material 804 is patterned into a longitudinal trench shape in order to form the insulating portions 411 in the resist material 804. Subsequently, the third interlayer insulating films 310c′ and 310d are selectively etched away with the resist material 804 as a mask by utilizing a dry etching method, thereby forming the longitudinal trenches.

As shown in FIG. 6D, after the resist material 804 has been removed away, the longitudinal trenches 805 are covered, and an oxide film 806 is laminated in order to form the insulating portions 411. At this time, the oxide film 806 is deposited under a deposition condition which is poor in coverage property, for example, at a low temperature, and at the low degree of vacuum or by using monosilane or the like so as not to fill the longitudinal trenches 805 with the oxide film 806, thereby making it possible to obtain the desired shape.

It is noted that in this case, the longitudinal trenches 805 are not positively filled with the air. The reason for this is because even when the longitudinal trenches 805 are not filled with the air in the phase of manufacturing of the liquid crystal display device 2, the air is naturally filled in the voids 411a of the insulating portions 411. For example, when a gas other than the air is desired to be filled in the voids 411a of the insulating portions 411, it is only necessary to fill the gases in the longitudinal trenches 805 before (or after) formation of the oxide film 806. Likewise, the air may be filled in the longitudinal trenches 805. The third interlayer insulating film 310c′ and the oxide film 806 compose the third interlayer insulating film 310c.

As shown in FIG. 6E, the light blocking film 305 and the like are formed on the oxide film 806 as a part of the interlayer insulating film 310, thereby obtaining the liquid crystal display device 2 according to the second embodiment of the present disclosure.

As has been described, according to the liquid crystal display device 2 of the second embodiment, even when the insulating portions 411 are formed across the parts of the third and fourth interlayer insulating films 310c and 310d so as to hold the signal wiring 306 between the insulating portions 411, the insulating portions 411 are formed so as to surround the channel portion 308 of the transistor, whereby the incident light can be prevented from entering the channel portion 308 of the transistor, the photo-leakage current generated in the transistor can be reduced, and thus the image quality of the liquid crystal display device 2 can be improved.

### Third Embodiment

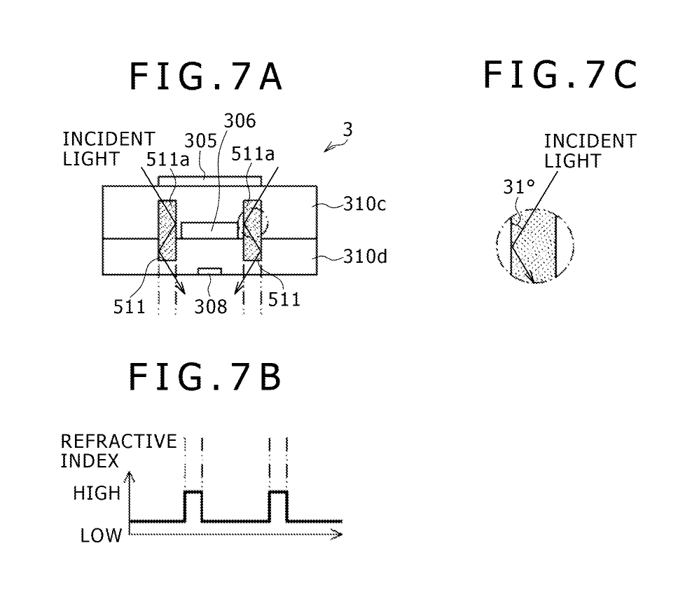

Next, a liquid crystal display device 3 according to a third embodiment of the present disclosure will be described in detail with reference to FIGS. 7A to 7C. The liquid crystal display device 3 has the same structure as that of the liquid crystal display device 2 of the second embodiment except for a refractive index of an insulating portion 511. It is noted that the same portions as those in the liquid crystal display device 1 of the first embodiment are designated by the same reference numerals or symbols, respectively, and a description thereof is omitted here for the sake of simplicity

A void 511a of each of the insulating portions 511, for example, is filled with a high refractive index material. Therefore, as shown in FIG. 7B, the refractive index of each of the insulating portions 511 in the liquid crystal display device 3 of the third embodiment is substantially determined depending on the high-refractive index material filled in each of the voids 511a, that refractive index thereof is higher than that of each of the third and fourth interlayer insulating films 310c and 310d. The high-refractive index material, for example, includes SIN or the like. In this case, each of the third and fourth interlayer insulating films 310c and 310d is made of SiO₂. A refractive index of SIN is 1.72. Since the refractive index of SiO₂ is 1.46, a difference in refractive index between the insulating portion 511, and each of the third and fourth interlayer insulating films 310c and 310d is 0.26. The third and fourth interlayer insulating films 310c and 310d have a structure in which the opening area 23 and the non-opening area 25 is separated from each other through the wall surface having the refractive index of 0.26 by the insulating portion 511. In a word, the insulating portion 511 is provided approximately across the entire film thickness direction in the third and fourth interlayer insulating films 310c and 310d. The third and fourth interlayer insulating films 310c and 310d are partitioned into a portion corresponding to the opening area 23, and a portion corresponding to the non-opening area 25 by the insulating portion 511.

In this case, as shown in FIG. 7A, the incident light which has reached the surface of the insulating portion 511 travels from the low-refractive index layer (the third, fourth interlayer insulating film 310c, 310d) to the high-refractive index layer (the insulating portion 511) to enter the inside of the insulating portion 511. When the incident light which has entered the insulating portion 511 reaches the surface of the insulating portion 511 facing the incidence side, that incident light travels from the high-refractive index layer (the insulating portion 511) to the low-refractive index layer (the third, fourth interlayer insulating film 310c, 310d), and is then internally reflected by the insulating portion 511 to travel toward the center of the insulating portion 511 again.

FIG. 7C is a view showing a portion surrounded by a circle indicated by a dashed line in FIG. 7A. As shown in FIG. 7C, the incident light whose incident angle is equal to or smaller than a critical angle (31° in this case) is totally reflected. Therefore, the incident light which has entered the inside of the insulating portion 511 is repetitively totally reflected on the surface of the insulating portion 511. Since the insulating portion 511 functions as a so-called waveguide, it is possible to reduce the incident light entering the channel portion 802 of the transistor.

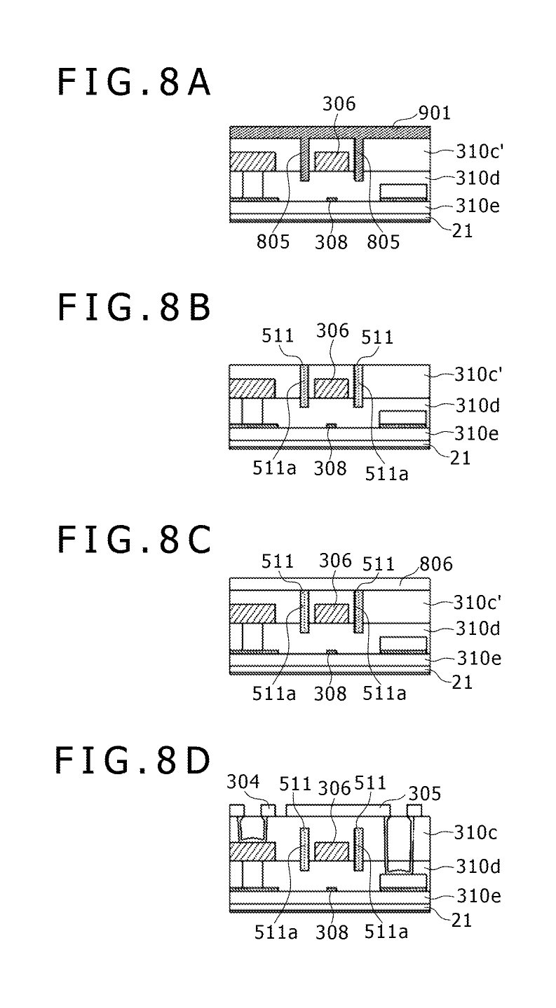

Next, a method of manufacturing the liquid crystal display device 3 will be described in detail with reference to FIGS. 8A to 8D. Since up to the process for forming the longitudinal trenches 805 in the third and fourth interlayer insulating films 310c and 310d is the same as that shown in FIGS. 6A to 6D, a description thereof is omitted here for the sake of simplicity.

As shown in FIG. 8A, after completion of the formation of the longitudinal trenches 805, a high-refractive index material (SIN in this case) 901 is deposited by utilizing a low-pressure CVD method. Next, as shown in FIG. 8B, an unnecessary part of the high-refractive index material 901 running over from the longitudinal trenches 805 is removed away by carrying out either etchback or a CMP treatment, thereby forming the insulating portions 511.

After that, as shown in FIG. 8C, the oxide film 806 is laminated, and the light blocking film 305 and the like are formed on the oxide film 806. Both of the third insulator insulating film 310c′ and the oxide film 806 form the third interlayer insulating film 310c. It is noted that the deposition of the oxide film 806 may be omitted, and after completion of the formation of the insulating films 511, the light blocking film 305 and the like may be directly formed on the insulating portions 511. In this case, the third insulator insulating film 310c′ becomes the third interlayer insulating film 310c.

As described above, according to the liquid crystal display device 3 of the third embodiment, since even when the high-refractive index material is filled in each of the insides of the voids 511a of the insulating portions 511, each of the insulating portions 511 functions as the waveguide, the incident light can be prevented from entering the channel portion 308 of the transistor, the photo-leakage current generated in the transistor can be reduced, and thus the image quality of the liquid crystal display device 3 can be improved.

It is noted that although in the third embodiment, the description has been given with respect to the case where the insulating portions 511 are applied instead of applying the insulating portions 411 in the liquid crystal display device 2 of the second embodiment, the insulating portions 511 may be applied instead of applying the insulating portions 311 in the liquid crystal display device 1 of the first embodiment.

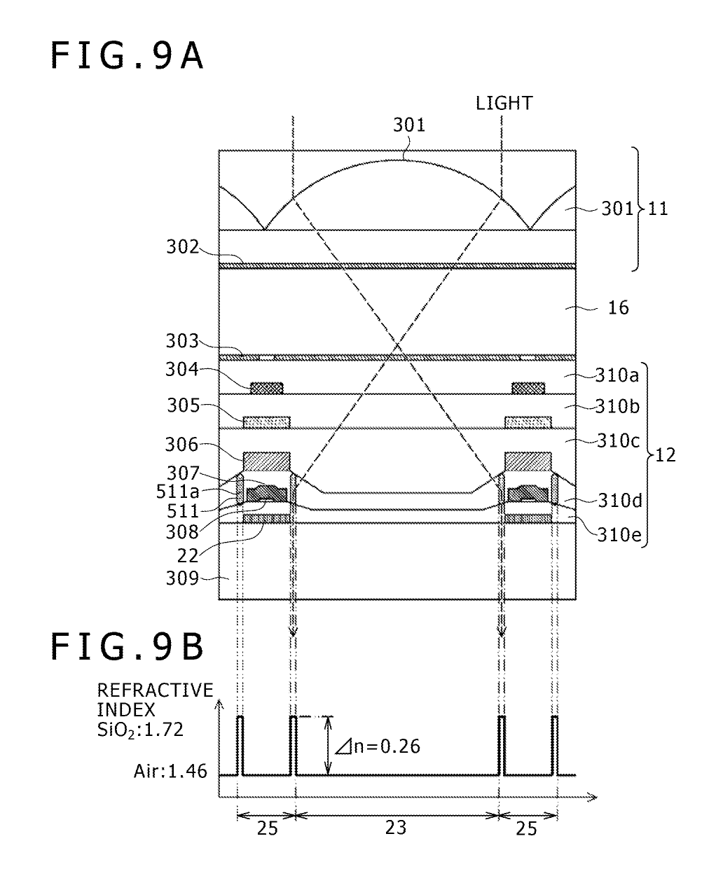

FIGS. 9A and 9B show a liquid crystal display device according to a change of the third embodiment in which the insulating portions 511 are applied instead of applying the insulating portions 311 in the liquid crystal display device 1 of the first embodiment. As shown in FIGS. 9A and 9B, a refractive index of the insulating portion 511 is made higher than that of the fourth interlayer insulating film 310d, whereby the insulating portion 511 functions as the waveguide, and thus the incident light which has reached the surface of the insulating portion 511 is directly emitted from a lower end of the insulating portion 511. As a result, it is possible to prevent the incident light from entering the channel portion 308 of the transistor.

### Fourth Embodiment

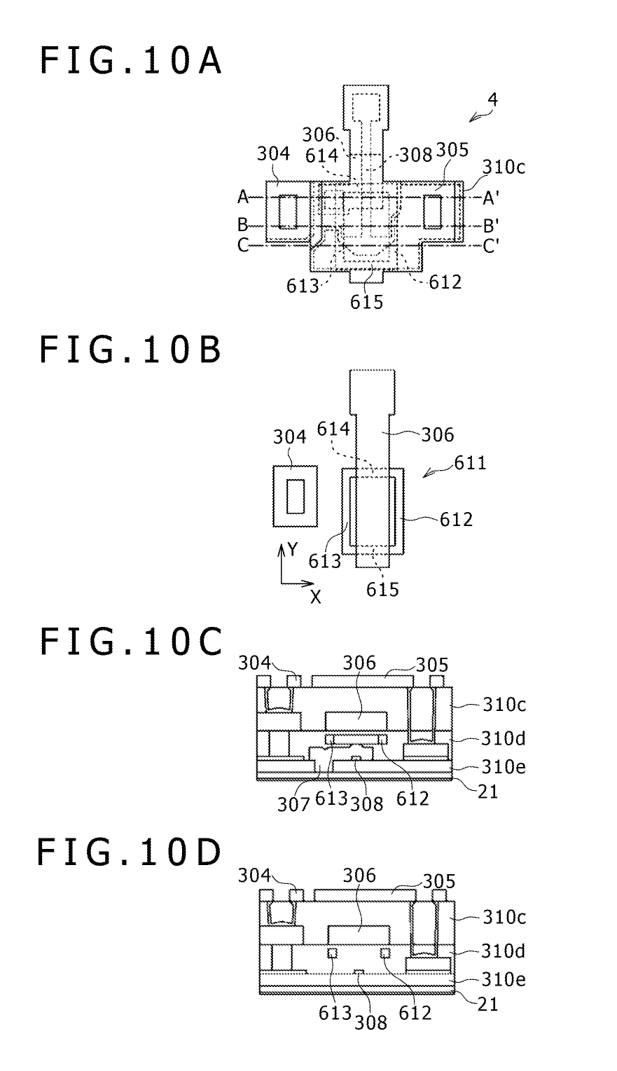

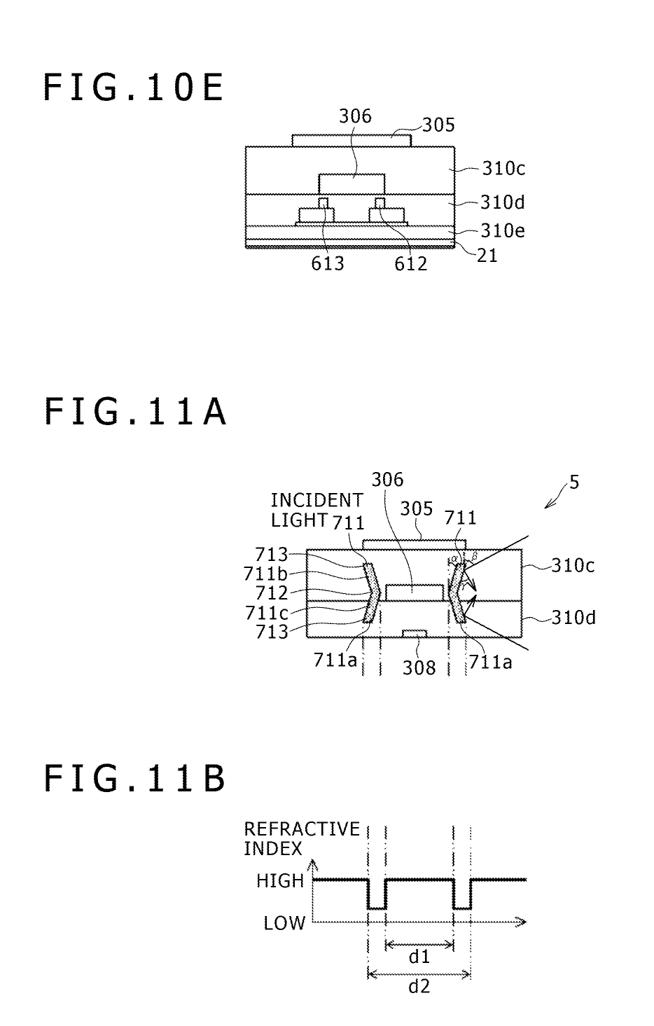

A liquid crystal display device 4 according to a fourth embodiment of the present disclosure will be described in detail hereinafter with reference to FIGS. 10A to 10E. The liquid crystal display device 4 of the fourth embodiment has the same structure as that of the liquid crystal display device 2 of the second embodiment except for a shape of an insulating portion 611. It is noted that the same portions as those in the liquid crystal display device 1 of the first embodiment are designated by the same reference numerals or symbols, respectively, and a description thereof is omitted here for the same of simplicity.

FIG. 10A is a top plan view when the non-opening area 25 of the third interlayer insulating film 310c is viewed from the second interlayer insulating film 310b side. FIG. 10B is a top plan view in which the layer of the third interlayer insulating film 310c is excluded from FIG. 10A. As shown in FIG. 10B, the insulating portions 611 in the liquid crystal display device 4 of the fourth embodiment has such a rectangular frame-like shape as to surround a part of the signal wiring 306.

FIG. 10C is a cross sectional view taken on line A-A′ of FIG. 10A, FIG. 10D is a cross sectional view taken on line B-B′ of FIG. 10A, and FIG. 10E is a cross sectional view taken on line C-C′ of FIG. 10A.

The insulating portion 611 has a first insulating portion 612, a second insulating portion 614, a third insulating portion 613, and a fourth insulating portion 615. In this case, the first insulating portion 612 is provided approximately in parallel with the signal wiring 306. The second insulating portion 614 is provided approximately at right angles with the first insulating portion 612. The third insulating portion 613 is provided approximately in parallel with the first insulating portion 612. Also, the fourth insulating portion 615 is provided approximately in parallel with the second insulating portion 614. Each of the first to fourth insulating portions 612 to 615 has an approximately rectangular parallelepiped-like shape. One end of the first insulating portion 612 contacts one end of the second insulating portion 614, and the other end of first insulating portion 612 contacts one end of the fourth insulating portion 615. One end of the third insulating portion 613 contacts the other end of the second insulating portion 614, and the other end of the third insulating portion 613 contacts the other end of the fourth insulating portion 615. Therefore, the insulating portion 611 has the rectangular frame-like shape. Also, as shown in FIG. 10A, the channel portion 308 of the transistor is disposed inside the frame of the insulating portion 611 in planar view.

As has been described, in the liquid crystal display device 4 of the fourth embodiment, the insulating portion 611 is formed so as to surround the four sides of the channel portion 308 of the transistor instead of surrounding the both sides of the channel portion 308. As a result, the more quantity of light can be prevented from entering the channel portion 308 of the transistor, the photo-leakage current generated in the transistor can be reduced, and thus the image quality of the liquid crystal display device 4 can be improved.

It is noted that although in the third embodiment, the description has been given with respect to the case where the insulating portions 611 are applied instead of applying the insulating portions 411 in the liquid crystal display device 2 of the second embodiment, the insulating portion 611 may also be applied instead of applying any of the insulating portions 311 and 511 of the liquid crystal display devices 1 and 3 of the first and third embodiments.

In addition, although in the fourth embodiment described above, the ends of the first to fourth insulating portions 612 to 615 in the manner as described above, it is only necessary to surround the channel portion 308 by the insulating portion 611. Thus, the first to fourth insulating portions 612 to 615 may also be disposed at given distances, respectively, or any one or more of the first to fourth insulating portions 612 to 615 may also be omitted.

### Fifth Embodiment

A liquid crystal display device 5 according to a fifth embodiment of the present disclosure will be described in detail hereinafter with reference to FIGS. 11A and 11B. The liquid crystal display device 5 of the fifth embodiment has the same structure as that of the liquid crystal display device 2 of the second embodiment except for a shape of an insulating portion 711. It is noted that the same portions as those in the liquid crystal display device 1 of the first embodiment are designated by the same reference numerals or symbols, respectively, and a description thereof is omitted here for the sake of simplicity.

The insulating portion 711 is a portion in which void 711a is formed in each of the third and fourth interlayer insulating films 310c and 310d, and is also a portion in which the air is held in the void 711a. The insulating portions 711 are formed so as to surround the both sides of the channel portions 308 of the transistor from the upper portion. Each of the third and fourth interlayer insulating films 310c and 310d, for example, is made of SiO₂, and a refractive index thereof is 1.46. The refractive index of the insulating portion 711 is 1.00 because the insulating portion 711 is substantially made of the air held in the void 711a. Therefore, a difference in refractive index between each of the third and fourth interlayer insulating films 310c and 310d, and the insulating film 711 becomes 0.46. As has been described, each of the insulating portions 711 has the refractive index different from that of the interlayer insulating film (the third, fourth insulating films 310c, 310d in the second embodiment) in which the insulating portion 711 is provided.

As shown in FIG. 11A, the insulating portion 711 has a bent portion 712. A distance, d1, between end portions 713 of the insulating portions 711 is shorter than a distance, d2, between the bent portions 712. The insulating portions 711 are formed in such a way that a portion (the bent portion 712) in the vicinity of the center thereof (in the vertical direction in FIG. 11A) becomes closer to the channel portion 308 of the transistor than each of portions (the end portions 713) in the vicinities of the both ends thereof. An insulating portion 711b on the counter substrate 11 side with respect to the bent portion 712, or an insulating portion 711c on the glass substrate 309 side with respect to the bent portion 712 is formed so as to be inclined at an angle, α, with respect to the film thickness direction.

The bent portion 712 is provided in the insulating portions 711 in such a manner, whereby the incident angle of the incident light reaching the surface of the insulating portion 711 becomes easy to become equal to or smaller than the critical angle, and thus a quantity of incident light totally reflected by the insulating portion 711 is increased.

For example, when the insulating portion 311 each of whose four constituent portions has the approximately rectangular parallelepiped-like shape as with the first embodiment, an angle (incident angle), γ, between the light made incident to the insulating portion 311, and the insulating portion 311 becomes equal to an angle, β, between the incident light and the film thickness direction. On the other hand, when the bent portion 712 is formed in the insulating portion 711 as with the fifth embodiment, an angle (incident angle), γ, between the light made incident from the micro-lens 301 side to the insulating portion 711b, and the insulating portion 711b becomes an angle obtained by subtracting the angle, α, between the film thickness direction and the insulating portion 710b from the angle, β, between the incident light and the film thickness direction (γ=β−α). Therefore, even when the angle, β, between the incident light and the film thickness direction is equal to or larger than the critical angle, the angle, β, is equal to or smaller than the critical angle, +α, the incident light is easy to totally reflect in the insulating portion 711 because the angle (incident angle), γ, between the incident light and the insulating portion 711b becomes equal to or smaller than the critical angle.

Note that, the angle, γ, between the light made incident from the micro-lens 301 side to the insulating portion 711c, and the insulating portion 711c becomes γ=β+α. Therefore, even when the angle, β, at which the light makes with the film thickness direction is small, the light made incident from the microlens 301 side to the insulating portion 711c becomes easy to transmit the insulating portion 711c. However, even when the light which has been made incident from the microlens 301 side to the insulating portion 711c is transmitted through the insulating portion 711c, the possibility that the incident light thus transmitted is transmitted through the lower portion of the channel portion 308 is high. Thus, the photo-leakage current is hard to generate in the channel portion 308 of the transistor due to that incident light.

On the other hand, when the reflected light into which the light made incident from the microlens 301 is reflected within the drive element substrate 12, for example, is made incident from the glass substrate 309 side to the insulating portion 711c, the reflected light thus made incident thereto becomes easy to totally reflect similarly to the case where the light is made incident from the microlens 301 to the insulating portion 711b.

As has been described, in the liquid crystal display device 5 of the fifth embodiment, the insulating portion 711 has the bent portion 712, whereby a quantity of incident light totally reflected by the insulating portion 711 can be increased, a quantity of light entering the channel portion 308 of the transistor can be further reduced, and thus the generation of the photo-leakage current can be further suppressed.

It is noted that although in the fifth embodiment, the description has been given with respect to the case where the insulating portions 611 are applied instead of applying the insulating portions 411 in the liquid crystal display device 2 of the second embodiment, the insulating portion 711 may also be applied instead of applying any of the insulating portions 311, 511, and 611 of the liquid crystal display devices 1, 3, and 4 of the first, third, and fourth embodiments.

When the insulating portion 711 is used instead of using the insulating portion 611 in the liquid crystal display device 4 of the fourth embodiment, an insulating portion which is bent inversely to the case of the insulating portion 711 in the liquid crystal display device 5 of the fifth embodiment, that is, an insulating portion in which the distance, d1, between the end portions 713 is longer than the distance, d2, between the bent portions 712 may also be used.

Finally, the embodiments described above are merely the exemplifications of the present disclosure, and thus the present disclosure is by no means limited thereto. For this reason, even in the case other than the embodiments described above, it is to be understood that various changes can be made in accordance with the design or the like without departing from the technical idea of the present disclosure.

The present technology contains subject matter related to that disclosed in Japanese Priority Patent Application JP 2011-076112 filed in the Japan Patent Office on Mar. 30, 2011, the entire content of which is hereby incorporated by reference.

What is claimed is:

1. A liquid crystal display device, comprising:
a drive element substrate having plural interlayer insulating films laminated thereon, and having a non-opening area in which signal lines and a transistor are provided and an opening area in which none of said signal lines and said transistors is provided in said plural interlayer insulating films; and
a counter substrate provided so as to face said drive element substrate through a liquid crystal,
wherein said drive element substrate includes
an insulating portion which is provided in the interlayer insulating film(s) between said non-opening area and said opening area, and whose refractive index is different from that of (each of) the interlayer insulating film(s), and
a light blocking film provided between said insulating portion and said counter substrate.

2. The liquid crystal display device according to claim 1, wherein the refractive index of said insulating portion is lower than that of said interlayer insulating film.

3. The liquid crystal display device according to claim 1, wherein the refractive index of said insulating portion is higher than that of said interlayer insulating film.

4. The liquid crystal display device according to claim 1, wherein said insulating portion is provided between said signal line and said opening area so as to surround a circumference of said transistor.

5. The liquid crystal display device according to claim 1, wherein said insulating portion has a first insulating portion, a second insulating portion provided approximately at right angles with said first insulating portion, a third insulating portion provided approximately in parallel with said first insulating portion, and a fourth insulating portion provided approximately in parallel with said second insulating portion.

6. The liquid crystal display device according to claim 1, wherein said insulating portion has a bent portion.

7. A method of manufacturing a liquid crystal display device including a drive element substrate having a non-opening area in which signal lines and a transistor are provided and an opening area in which none of said signal lines and said transistor is provided, and a counter substrate provided so as to face said drive element substrate through a liquid crystal, said manufacturing method comprising:
forming plural interlayer insulating films, and forming said signal lines and said transistors in said non-opening area in the interlayer insulating film(s);
forming an insulating portion whose refractive index is different from that of (each of) the interlayer insulating film(s) between said non-opening area and said opening area of the interlayer insulating film(s); and
forming a light blocking film between said insulating portion of said non-opening area, and said counter substrate.
